(19) United States
(12) Patent Application Publication
(10) Pub. No.: US 2026/0029442 A1
(43) Pub. Date: Jan. 29, 2026

(54) Super Sensitive Wearable Digital Device for Non-contact Voltage Detection

(71) Applicant: University of the Incarnate Word, San Antonio, TX (US)

(72) Inventors: Okan Caglayan, San Antonio, TX (US); Ricky Perez, JR., San Antonio, TX (US); Robert DeMarce, San Antonio, TX (US); Aidan Cullen Quinn, San Antonio, TX (US); Emily Marie Saenz, San Antonio, TX (US); Lucas Bryand, San Antonio, TX (US)

(21) Appl. No.: 19/282,957

(22) Filed: Jul. 28, 2025

Related U.S. Application Data
(60) Provisional application No. 63/675,886, filed on Jul. 26, 2024.

(51) Int. Cl. G01R 19/155; G01R 33/02; G01W 1/02; G06F 1/16; G06F 3/147; G06F 3/16

(52) U.S. Cl. CPC G01R 19/155; G01R 33/0206; G01W 1/02; G06F 1/163; G06F 3/147; G06F 3/16

(57) ABSTRACT

A wearable voltage detector that uses a magnetometer to sense electro-magnetic fields within range of the detector. The wearable voltage detector converts the electro-magnetic data into voltage. The wearable voltage detector is programed to a pre-set voltage threshold via a microcontroller. When the voltage detected by the wearable voltage detector reaches the pre-set voltage threshold, the wearable voltage detector notifies the user via a buzzer, a light, and/or a screen display.

### CROSS-REFERENCES TO RELATED APPLICATIONS

This application claims the benefit of the filing date of provisional patent application No. 63/675,886 filed Jul. 26, 2024.

### STATEMENT REGARDING FEDERALLY SPONSORED RESEARCH OR DEVELOPMENT

Not applicable.

### BACKGROUND OF THE INVENTION

### 1. Field of the Invention

Electrical enclosures commonly found in residential and commercial facilities can contain high voltages ranging from 110 volts (V) to thousands of volts that may cause injury or damage. Regulations covering these enclosures, including Underwriter's Laboratories (UL) and National Fire Protection Association (NFPA), require that high voltages inside these enclosures be verified to be absent before any updates, repair, or maintenance work can begin.

When working in areas where there may be live electricity, it is imperative for individuals, such as electricians, linemen, plumbers, firemen, etc., to quickly determine if the electrical units, such as devices, switches, outlets, breaker boxes, systems, are still energized.

### 2. Description of the Related Art

The current state of voltage detector or tester technology accessible to workers is mostly limited to tools which are often carried in a bag, worn on clothing, and thus are not readily available when needed, may be misplaced or otherwise forgotten. Thus, there is a need for a wearable digital device that is practical to utilize in day-to-day operations to detect presence of electricity and simultaneously provides situational awareness by measuring environmental conditions.

### BRIEF SUMMARY OF THE INVENTION

The present invention is a multi-sensor wearable digital device that can detect the presence of voltage by measuring electromagnetic fields and monitoring environmental conditions to protect individuals who may be exposed to hazardous voltages. The present invention provides real-time feedback about the state of electrical equipment, identifies a potential electrical hazard, and prevents inadvertent contact for safer work practices.

A unique capability of the present invention is that it can detect the presence of alternating current (AC) and direct current (DC) voltages by measuring electromagnetic fields and monitoring environmental conditions to protect individuals who may be exposed to hazardous voltages.

### BRIEF DESCRIPTION OF THE SEVERAL VIEWS OF THE DRAWINGS

FIG. 1 is a perspective view of an embodiment of the Super Sensitive Wearable Digital Device for Non-contact Voltage Detection (“Detection Device”).

FIG. 2 is an top internal view of an embodiment of the Detection Device.

FIG. 3 is a side internal view of an embodiment of the Detection Device.

FIG. 4 is a side internal view of an embodiment of the Detection Device.

FIG. 5 a circuit diagram of an embodiment of the Detection Device.

FIG. 6 is a bottom internal view of an embodiment of the Detection Device.

### DETAILED DESCRIPTION OF THE INVENTION

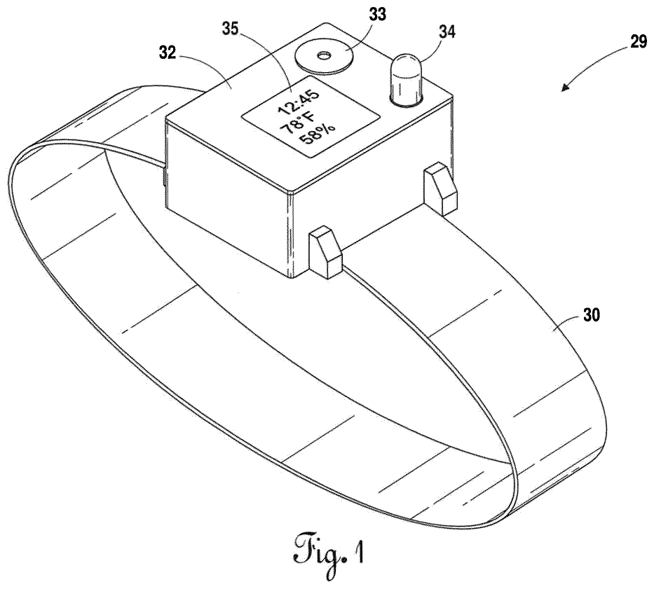

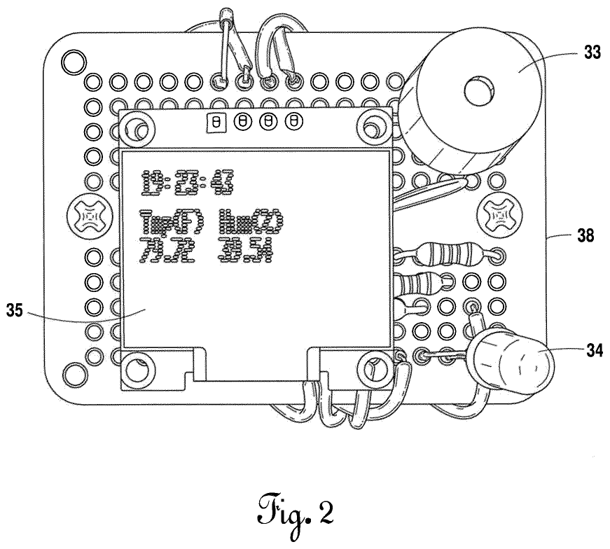

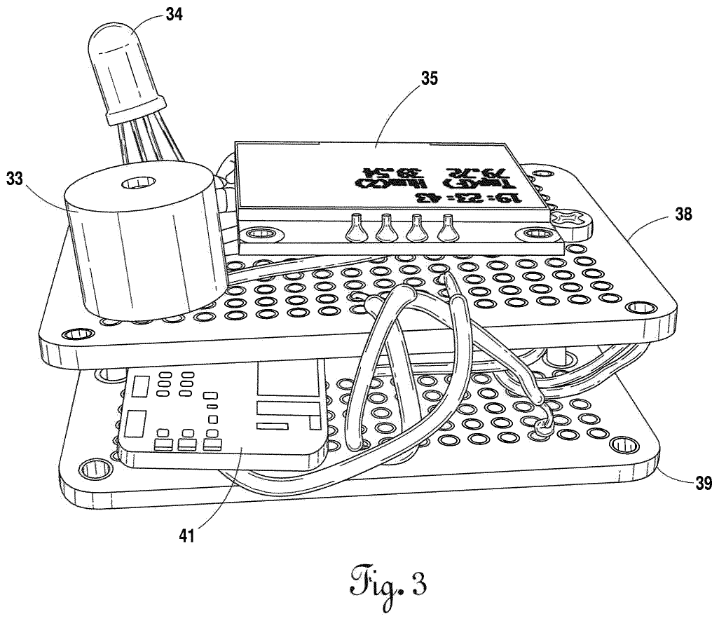

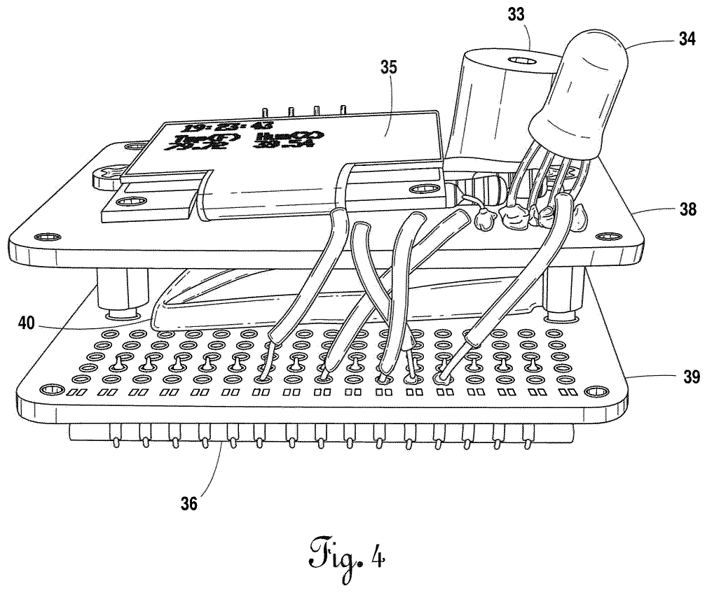

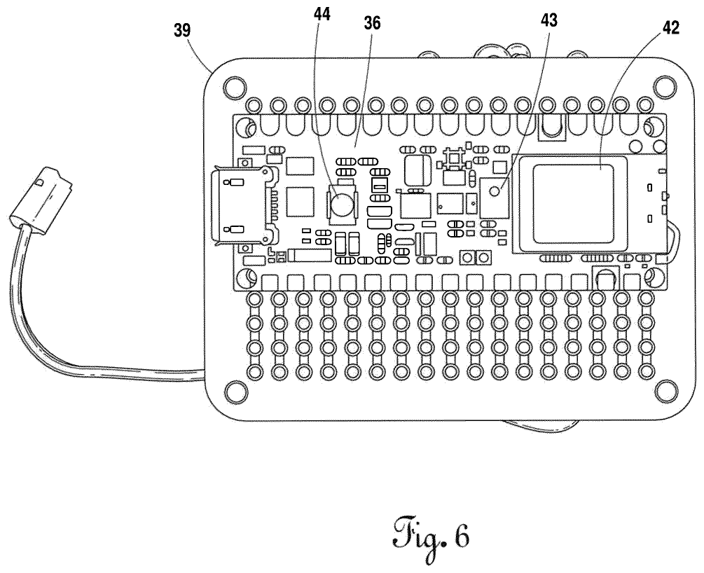

An embodiment of the Super Sensitive Wearable Digital Device for Non-contact Voltage Detection (“Detection Device”) is described with reference to FIGS. 1-6.

With reference to FIG. 1, the Detection Device 29 comprises a strap 30 and a housing 32. In some embodiments, the Detection Device further includes a clasp 31 (not shown) that connects two sections of the strap 30.

With reference to FIGS. 1-4 and 6, the Detection Device 29 further comprises a buzzer 33, an LED light 34, a display screen 35, a battery 40, a charger 41, a microcontroller 36, a first circuit board 38, and a second circuit board 39. Those of ordinary skill in the art understand that suitable wires and resistors are also present.

In some embodiments, the microcontroller 36 is a low voltage microcontroller with a 64 MHz ARM® Cortex®-M4F (with FPU and 32-bit), such as the Arduino Nano 33 BLE Sense Rev2. The microcontroller 36 comprises a magnetometer 42, a humidity sensor 43, and a temperature sensor 44. In the embodiment shown in the figures, the magnetometer 42, humidity sensor 43, and temperature sensor 44 are integral the microcontroller 36.

In some embodiments, the magnetometer 42 is a BMM 150 3-axis IMU, which is a 3-axis digital geomagnetic sensor with 0.3 T resolution with ±1300 T (x,y-axis), ±2500 T (z-axis). The magnetometer 42 is a digital magnetometer for detecting both AC and DC voltage. The integration of a digital magnetometer is an improvement over conventional designs that rely on coil antenna or capacitive plates. In the embodiment show in the Figs., the microcontroller 36 is located on the bottom of the second circuit board 39.

In some embodiments, the humidity sensor 43 and temperature sensor 44 are a combined unit, such as a HS3003 temperature and humidity sensor capable of providing 14-bit humidity and temperature output data with high accuracy. The integration of a environmental sensor fusion (temperature and humidity) within the same device to enable real-time situational awareness beyond voltage detection is an improvement over prior art voltage detection devices.

The Detection Device 29 further comprises a first circuit board 38 and a second circuit board 39. Those of ordinary skill in the art understand that the systems and methods disclosed herein could be incorporated via a single circuit board. The Detection Device 29 further comprises suitable wires and resistors.

The Detection Device 29 comprises a fully digital signal processing pipeline utilizing Arduino microcontrollers and I2C-based sensors, which avoids analog front-end or hybrid configurations.

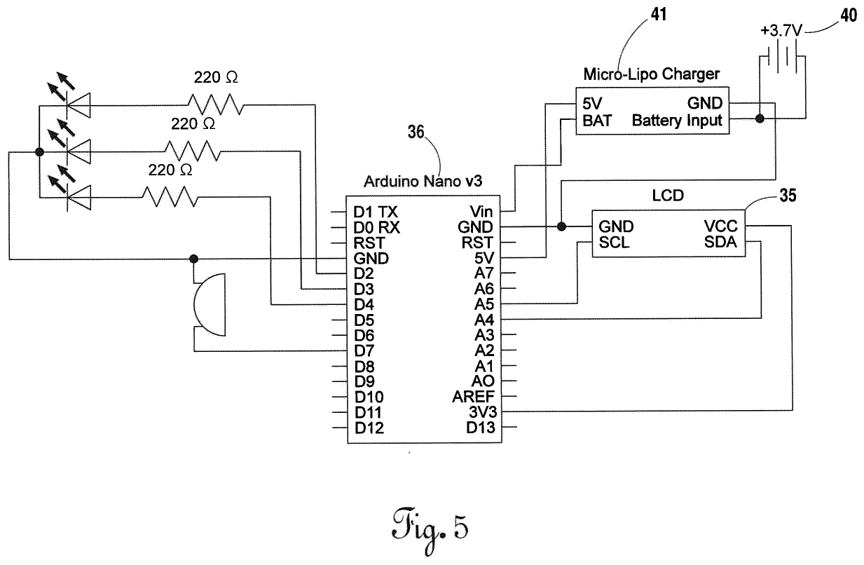

With reference to FIG. 5, a circuit diagram for an embodiment of the Detection Device 29 is shown.

In some embodiments, the charger 41 is a micro-lipo charger. In some embodiments, the battery 40 is a 3.7V/4.2V lithium polymer or lithium-ion rechargeable battery. The micro-lipo charger 41 can charge the battery 40 when the micro-lipo charger 41 is connected to a power source via a microUSB chord or other suitable connection.

The battery 40 provides power to the other components of the Detection Device 29.

The operation of the Detection Device 29 is described with reference to FIGS. 1 and 5. When powered on or placed into the armed mode, the Detection Device 29 continuously monitors electromagnetic fields via the magnetometer 42. The microcontroller 36 processes the sensor data in real time to calculate the vector magnitude of the magnetic field and determine the presence of nearby voltage sources.

In the embodiment described herein, the Detection Device 29 is capable of detecting direct current (DC) voltage sources at distances of approximately eight to twelve inches (twenty to thirty centimeters), and alternating current (AC) voltage sources—such as high-voltage utility lines—at distances of up to one meter. The microcontroller 36 analyzes the data captured by the magnetometer 42 and converts it into a detected voltage output 45, triggering an alert when field strength exceeds a defined threshold.

The microcontroller 36 is programed with a pre-set voltage 46. The pre-set voltage 46 is programmed by the user and/or the manufacture into the device by utilizing the microcontroller's 36 interface development environment (IDE). The pre-set voltage 46 may comprises a range of pre-set voltages. The pre-set voltage 46 was determined based on National Oceanic and Atmospheric Administration's (NOAA) geomagnetic calculator. The pre-set voltage was field tested to comply with the Occupational Safety and Health Administration (OSHA) operational and safety requirements for energized equipment.

When the detected voltage 45 equals or exceeds a pre-set voltage 46, the microcontroller 36 sends a millivolt signal 47 which activates an audible alert 48 via the buzzer 33, a visual alert 49 via the screen 35 and/or the light 34, or both an audible alert 48 and a visual alert 49.

When the wearer gets within range of an electromagnetic field that is above the preset level 46, the microcontroller 36 of the Detection Device 92 sends a signal 47 to the LCD Screen 35, the RGB LED 34, and/or the Buzzer 33. The LCD Screen 35, RGB LED 34, and/or the Buzzer 33 create an audible 84 and/or visual 49 alert to the wearer that an electromagnet field equal to or greater than the pre-set level has been detected.

The Detection Device is not limited to one specific pre-set voltage 46. The preset level 46 is variable and depends on several factors. By way of example, a device that will be used in San Antonio, Texas, the preset level is determined based on the geolocation of San Antonio, Texas. The National Oceanic and Atmospheric Administration (NOAA) has provided magnetic field (B) data specific to San Antonio, which was utilized to calculate the preset level in the International System of Units (SI) as illustrated in the following equation:

$$Equation for Magnitude of Magnetic Field$$

$$\vert B \vert = ( \sqrt{( {B}_{x} ) - ( {B}_{y} ) - ( {B}_{y} )} ) - ( {B}_{SA} )$$

In the equation above, |B| is the total magnitude of magnetic field, Bₓ, B_{y} and B_{z} are the measured magnitude of magnetic fields in x, y, z (axes) directions in three dimensional coordinate system by the sensor embedded into the Arduino microcontroller, B_{SA} is a constant value that is the magnitude of magnetic field of San Antonio, Texas (MF of SA,TX) published by NOAA. This constant is 45 μT in the above equation. The equation used to calculate the total magnitude of the magnetic field (|B|) results in the microTesla (μT) readings.

Based on experimental testing, it was determined that a magnetic field increase of 86 μT serves as an appropriate preset threshold to trigger the warning light, indicating potential electrical danger. This value was established through field testing involving various electrical devices and systems, including HVAC units, microwaves, refrigerators, and golf cart batteries. The tests showed that energized equipment commonly produced field strength increases in this range. For example, in San Antonio, Texas, the Earth's ambient magnetic field is approximately 45 μT. When this is combined with the preset threshold of 86 μT, the device would trigger a safety alert at a total measured field strength of approximately 131 μT. The preset threshold of 86 μT is consistent across locations, while the device can be calibrated to local geomagnetic conditions to maintain accurate detection and avoid false positives. The wearable detection device is capable of sensing the presence of electromagnetic fields generated by electrical sources at various distances. For direct current (DC) voltage sources (e.g. 48 V battery in a solar power system), the device detects field variations at distances ranging from approximately eight to twelve inches (twenty to thirty centimeters), depending on the load and conductor configuration. For alternating current (AC) high-voltage sources (e.g., 11 kV utility lines), the sensor reliably identifies the field at distances up to one meter. This detection capability is achieved using a BMM150 digital 3-axis magnetometer integrated with a microcontroller performing real-time vector field magnitude computations.

The present invention is capable of simultaneously detecting AC and DC (such as golf cart, car, power tool batteries) electric potentials and incorporating environmental conditions that are based on humidity and temperature, which are major factors in creating hazardous voltages in a given space. The microcontroller has a built-in temperature and humidity sensor, which is HS3003. As temperature rises, the resistance of conductive materials increases causing more heat to be generated in the system. This would lead to overheating and potentially causing insulation breakdown. If there is a low temperature it would reduce resistance and lead to higher current flows stressing the system. High humidity can lead to condensation introducing a conductive path where there should be none which could cause short circuits and increase the risk of electrical shock. The Detection Device 29 provides real time temperature and humidity data to the wearer.

The present invention is a compact wearable form factor that provides both visual and audible alerts, with an optimized detection range of 8-12 inches (20-30 centimeters) for DC and up to 1 meter for AC. The device is specifically designed for utility field technicians, unlike high-voltage-only detectors such as the Extech DV690.

The present invention is a novel combination of the following specific technical features: a digital magnetometer for detecting both AC and DC voltage; environmental sensor fusion (temperature and humidity) in the same device; a fully digital processing pipeline; and compact wearable form factor with a range of 8-12 inches (20-30 centimeters) for DC and up to 1 meter for AC, making the device suitable for utility field workers.

1. A wearable voltage detector comprising:
a microcontroller, a magnetometer, a temperature sensor, a humidity sensor, a screen, a buzzer, and a signal light.

2. The wearable voltage detector of claim 1 further comprising a screen display.

3. The wearable voltage detector of claim 2 wherein the screen display is a liquid-crystal display.

4. The wearable voltage detector of claim 3 further comprising a battery and a charger.

5. The wearable voltage detector of claim 4 wherein the charger is a micro-lipo charger.

6. The wearable voltage detector of claim 1 wherein the microcontroller is a low voltage microcontroller with a sixty-four megahertz processor.

7. The wearable voltage detector of claim 1 wherein the magnetometer is a three-axis digital geomagnetic sensor.

8. A method of detecting voltage using a wearable device comprising:
calculating a dangerous voltage threshold;
a magnetometer of the wearable device measuring electromagnetic fields that are within a range of the wearable device and obtaining surrounding electromagnetic field data;
the wearable device converting the surrounding electromagnetic field data into surrounding voltage data;
the wearable device comparing the surrounding voltage data to the dangerous voltage threshold;
the wearable device creating an alert when then surrounding voltage data equals and/or exceeds the dangerous voltage threshold.

9. The method of claim 8 wherein:
the alert is provided audibly via a buzzer of the wearable device.

10. The method of claim 8 wherein:
the alert is provided visually via a light.

11. The method of claim 8 wherein:
the alert is provided visually via a screen.

12. The method of claim 8 wherein:
the alert is provided visually via a light and a screen.

13. The method of claim 8 wherein:
the alert is provided audibly and visually.

14. The method of claim 8 wherein the magnetometer detects surrounding direct current and surrounding alternating current.

15. The method of claim 14 wherein the dangerous voltage threshold is variable based on the geolocation of the wearable device.

16. The method of claim 8 wherein:
the detection device further comprises a humidity sensor and a temperature sensor;
the humidity sensor detects humidity data;
the temperature sensor detects temperature data;
the detection device displays real time humidity and temperature data.

17. The method of claim 8 wherein:
the magnetometer is a digital magnetometer.

18. The method of claim 8 wherein the range is twenty to thirty centimeters for direct currents and up to one meter for alternating currents.
